(19) United States
(12) Patent Application Publication
(10) Pub. No.: US 2020/0357746 A1
(43) Pub. Date: Nov. 12, 2020

(54) SEMICONDUCTOR MODULE

(71) Applicant: ULTRAMEMORY INC., Tokyo (JP)

(72) Inventors: Yasuji KOSHIKAWA, Tokyo (JP); Fumitake OKUTSU, Tokyo (JP)

(21) Appl. No.: 16/765,099

(22) PCT Filed: Nov. 21, 2017
(86) PCT No.: PCT/JP2017/041887

§ 371 Date: May 18, 2020

(51) Int. Cl. H01L 23/538; H01L 23/40; H01L 23/00; H01L 25/065

(52) U.S. Cl. CPC H01L 23/5385; H01L 23/40; H01L 25/0657; H01L 23/5386; H01L 24/14

(57) ABSTRACT

The objective of the invention is to provide a semiconductor module allowing the bandwidth between an MPU and a DRAM to be improved. This semiconductor module 1 comprises a logic chip 20, a RAM unit 40 which is a multi-layer RAM module, a spacer 60 disposed stacked over the RAM unit 40 in the layering direction thereof, an interposer 10 electrically connected to each of the logic chip 20 and the RAM unit 40, and a connection part 50 establishing a connection allowing for communication between the logic chip 20 and the RAM unit 40. The logic chip 20 and the spacer 60 are disposed to be adjacent to one another in a direction intersecting with the layering direction of the RAM unit 40, and the RAM unit 40 is placed on the interposer 10 while one end portion thereof overlaps with one end portion of the logic chip 20 in the layering direction. The connection part 50 connects the one end portion of the RAM unit 40 to the one end portion of the logic chip 20.

### TECHNICAL FIELD

The present invention relates to a semiconductor module.

### BACKGROUND ART

In the related art, a volatile memory (RAM) such as a dynamic random access memory (DRAM) has been known as a storage device. DRAMs are required to have high performance of an arithmetic unit (hereinafter referred to as a logic chip) and a large capacity capable of withstanding an increase in amount of data. Therefore, the capacity has been increased by miniaturizing a memory (memory cell array, memory chip) and increasing the number of cells in a plane. On the other hand, this type of increase in capacity has reached its limit due to the weakness to noise caused by the miniaturization, the increase in die area, and the like.

Therefore, in recent years, a technology has been developed that realizes a large capacity by laminating a plurality of planar memories to form a three-dimensional (3D) structure. In addition, there has been proposed a semiconductor module that reduces an installation area of the logic chip and the RAM by disposing the logic chip and the RAM by lamination (refer to, for example, Patent Documents 1 and 2). Patent Document 1: Japanese Unexamined Patent Application (Translation of PCT Application), Publication No. 2014-512691 Patent Document 2: Japanese Unexamined Patent Application, Publication No. 2010-232659

### DISCLOSURE OF THE INVENTION

### Problems to be Solved by the Invention

With the increase in performance of the logic chip and the increase in amount of data, an improvement in communication rate between the logic chip and the RAM is also required along with the increase in capacity. Therefore, it is preferable to provide a semiconductor module capable of improving a bandwidth between the logic chip and the RAM.

An object of the invention is to provide a semiconductor module capable of improving a bandwidth between a logic chip and a RAM.

### Means for Solving the Problems

According to the invention, there is provided a semiconductor module including: a logic chip; a RAM unit which is a lamination-type RAM module; a spacer which is disposed to be laminated over the RAM unit along a lamination direction; an interposer which is electrically connected to each of the logic chip and the RAM unit; and a connection unit which communicably connects the logic chip and the RAM unit. The logic chip and the spacer are disposed to be adjacent to each other in a direction intersecting the lamination direction of the RAM unit, wherein the RAM unit is placed on the interposer, and one end of the RAM unit is disposed to overlap one end of the logic chip in the lamination direction. The connection unit communicably connects the one end of the RAM unit and the one end of the logic chip.

In addition, it is preferable that a pair of the RAM unit and the spacer are provided with the logic chip interposed therebetween, and the connection unit is provided for each of the RAM units.

In addition, it is preferable that a thickness of the spacer is substantially equal to a thickness to the logic chip.

In addition, it is preferable that a thickness of the spacer is larger than a thickness of the logic chip.

In addition, it is preferable that, among ends of the spacer, an end opposite to a side facing the logic chip is disposed to protrude from the RAM unit in a direction intersecting the lamination direction of the RAM unit.

In addition, it is preferable that the semiconductor module further includes a plurality of pillars which communicably connect the interposer and the logic chip, each pillar being longer than a thickness of the RAM unit in the lamination direction.

In addition, it is preferable that a plurality of the logic chips are provided for one interposer, and a pair of the RAM units and a pair of the spacers are provided for each of the logic chips. Effects of the Invention

According to the present invention, it is possible to provide a semiconductor module capable of improving a bandwidth between a logic chip and a RAM.

### BRIEF DESCRIPTION OF THE DRAWINGS

FIG. 1 is a schematic plan view illustrating a semiconductor module according to one embodiment of the present invention, excluding a spacer and a support. FIG. 2 is a schematic side view of a semiconductor module according to one embodiment. FIG. 3 is a schematic side view illustrating an MPU when manufacturing the semiconductor module according to one embodiment. FIG. 4 is a schematic side view of a connection unit provided in the MPU when manufacturing the semiconductor module according to one embodiment is manufactured. FIG. 5 is a schematic side view of pillars provided in the MPU when manufacturing a semiconductor module according to one embodiment. FIG. 6 is a schematic side view illustrating the RAM unit when manufacturing the semiconductor module according to one embodiment. FIG. 7 is a schematic side view of a connection unit provided in the RAM unit when manufacturing the semiconductor module according to one embodiment. FIG. 8 is a schematic side view of micro bumps provided in the RAM unit when manufacturing the semiconductor module according to one embodiment. FIG. 9 is a schematic side view illustrating a support when manufacturing the semiconductor module according to one embodiment. FIG. 10 is a schematic side view of the MPU provided on the support when manufacturing the semiconductor module according to one embodiment. FIG. 11 is a schematic side view of a spacer provided on the support when manufacturing the semiconductor module according to one embodiment. FIG. 12 is a schematic side view of the RAM unit provided on the support when manufacturing the semiconductor module according to one embodiment. FIG. 13 is a schematic plan view illustrating a semiconductor module according to a modified example of the present invention, excluding a spacer and a support.

### PREFERRED MODE FOR CARRYING OUT THE INVENTION

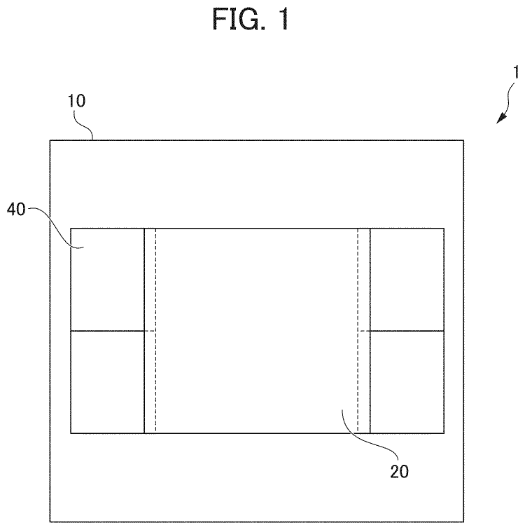

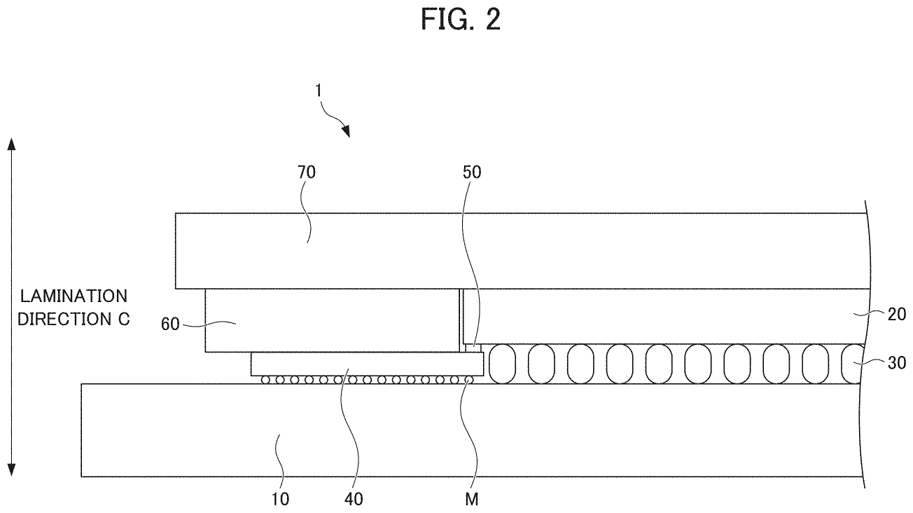

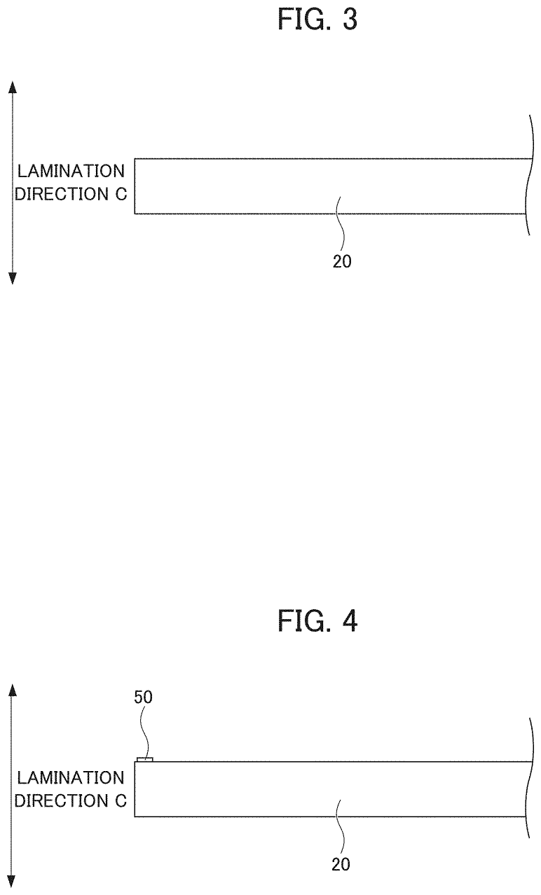

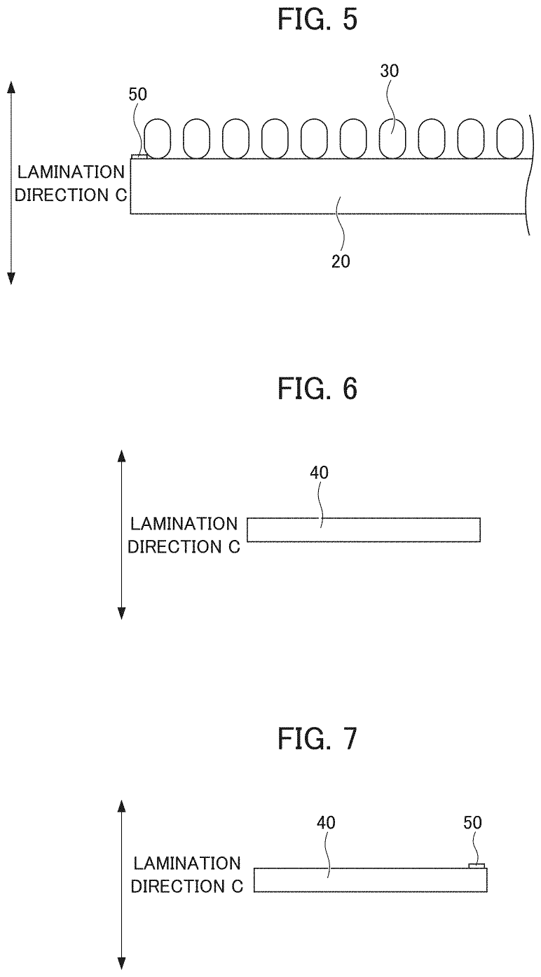

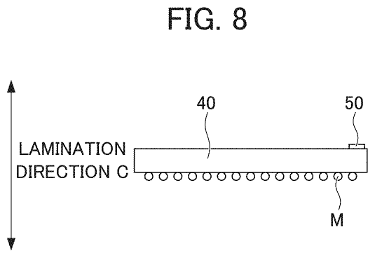

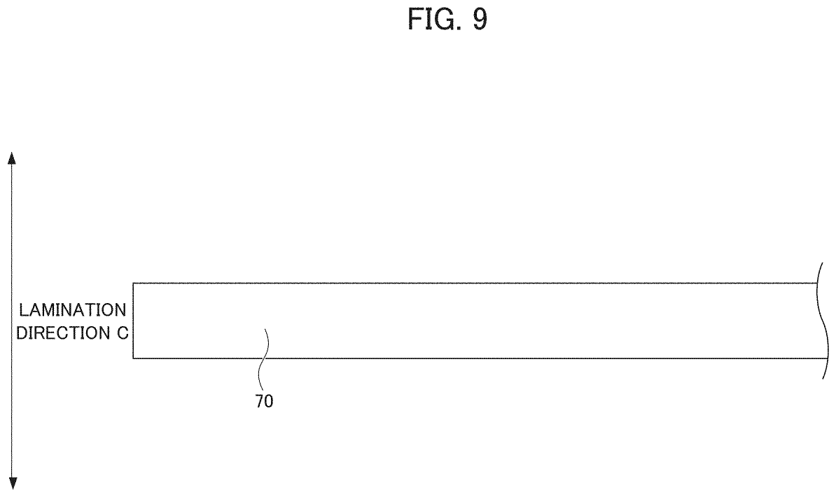

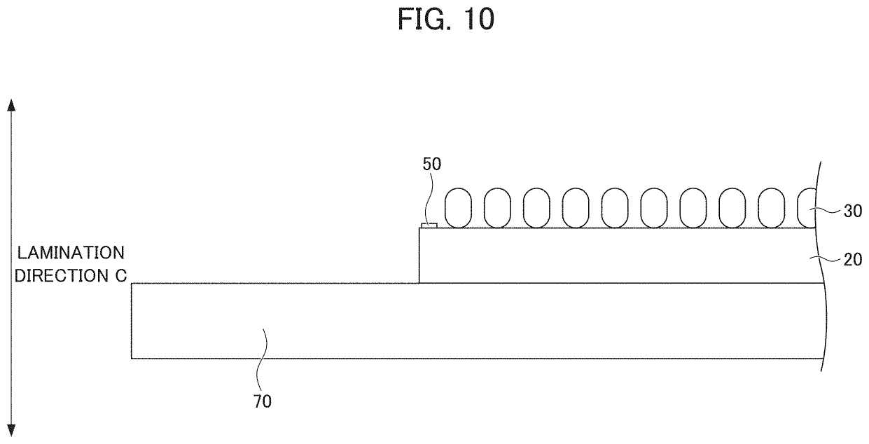

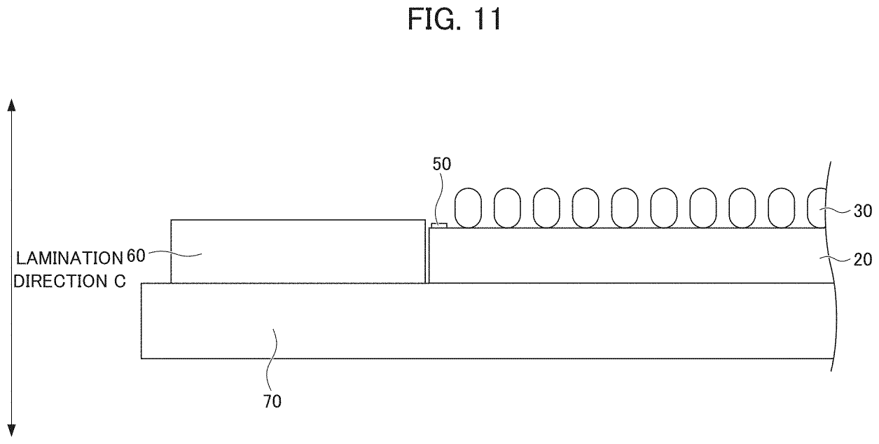

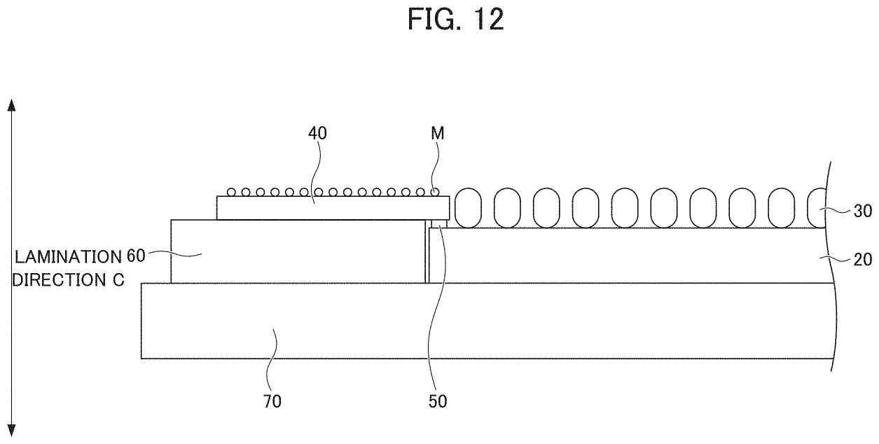

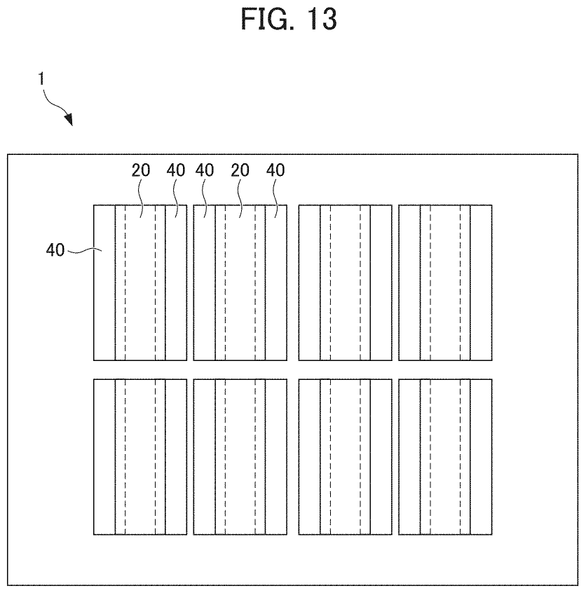

Hereinafter, a semiconductor module according to one embodiment of the present invention will be described with reference to FIGS. 1 to 13. The semiconductor module according to one embodiment is, for example, a system in a package (SIP) in which arithmetic units (hereinafter referred to as logic chips) and lamination-type RAMS are disposed on an interposer. The semiconductor module is disposed on a different interposer or a package substrate, and is electrically connected by using micro bumps, solder bumps, or the like. The semiconductor module is a device that can obtain power from different interposers and can transmit and receive data to and from different interposers. In addition, in the following embodiment, an MPU will be described as an example of a logic chip.

As illustrated in FIGS. 1 and 2, a semiconductor module 1 according to the present embodiment includes an interposer 10, an MPU 20, pillars 30, a RAM unit 40, a connection unit 50, a spacer 60, and a support 70.

As illustrated in FIGS. 1 and 2, the interposer 10 is a plate-like body having a rectangular shape in a plan view, and an electric circuit is formed therein. The interposer 10 is electrically connected to the MPU 20 and the RAM unit 40 to be described later. The interposer 10 is disposed on a different interposer (not illustrated) or a package substrate (not illustrated), and one surface (lower surface) thereof is electrically connected to the different interposer or the package substrate by using, for example, micro bumps (not illustrated) or solder bumps (not illustrated). In addition, in the following, a thickness direction of the interposer 10 will be described as a lamination direction C. In addition, in the lamination direction C, the surface side where the MPU 20 and the RAM unit 40 are disposed is described as upward. In addition, in the lamination direction C, the direction opposite to the upward is described as downward.

The MPU 20 is a plate-like body having a rectangular shape in a plan view. As illustrated in FIGS. 1 and 2, in the MPU 20, a circuit surface (not illustrated) that functions as a power supply terminal, a communication terminal, and a ground terminal is disposed on the lower surface side. The circuit surface of the MPU 20 is disposed facing the upper surface of the interposer 10.

A plurality of pillars 30 are disposed. The pillars 30 communicably connect the interposer 10 and the MPU 20. Specifically, one end of the pillar 30 is connected to the interposer 10, and the other end is connected to the circuit surface of the MPU 20. Each of the pillars 30 is longer than the thickness in the lamination direction C of the RAM unit 40 described later.

The RAM unit 40 is configured to include a lamination-type RAM module having a rectangular shape in a plan view. The RAM unit 40 is placed on the upper surface of the interposer 10 as illustrated in FIG. 2. One end of the RAM unit 40 is disposed so as to overlap one end of the MPU 20 in the lamination direction C with the later-described connection unit 50 therebetween. Specifically, one end of the RAM unit 40 is disposed so as to be interposed between one end of the MPU 20 and the interposer 10. The lower surface of the RAM unit 40 facing the upper surface of the interposer 10 is electrically connected to the interposer 10 by using micro bumps M. Although not particularly limited, a pair of the RAM unit 40 are provided so as to interpose the MPU 20 in a direction intersecting the lamination direction C. Specifically, in the present embodiment, although not particularly limited, four RAM units 40 may be disposed, and two RAM units 40 may be provided along each side on one side of the MPU 20 and one side on the opposite side. Accordingly, the distance between the pair of RAM units 40 interposing the MPU 20 is shorter than the length of one side of the MPU 20 and the other side thereof.

The RAM unit 40 is formed by laminating memory circuits (not illustrated). Specifically, the RAM unit 40 is formed by laminating dies (not illustrated) of a plate-like body having a rectangular shape in a plan view having a memory circuit on the upper surface in the lamination direction C. The die is an Si substrate in which circuits are formed therein, and each of the laminated dies is electrically connected to an adjacent die. A power supply terminal and a ground terminal connecting between the laminated dies are formed by, for example, bumpless TSV, and a signal line is formed by a TCI (ThruChip Interface). In addition, the phrase “electrically connected” is not limited to “directly connected”, but the phrase includes “indirectly connected” (for example, by using a magnetic field) like TCI.

The connection unit 50 is a communication interface that connects the MPU 20 and the RAM unit 40. The connection unit 50 is configured with, for example, a TCI, a Cu pad, or the like. The connection unit 50 communicably connects the MPU 20 and the RAM unit 40. The connection unit 50 is connected to one end of a surface (upper surface) of the RAM unit 40 opposite to the surface (lower surface) placed on the interposer 10. In addition, the connection unit 50 is connected to one end of a surface (lower surface) of the MPU 20 facing the interposer 10. Specifically, the connection unit 50 is connected to a portion of the upper surface of the RAM unit 40 facing the MPU 20 and a portion of the lower surface of the MPU 20 facing the RAM unit 40. The connection unit 50 is disposed in each of the RAM units 40. For example, in the present embodiment, the connection units 50 are disposed between the four RAM units 40 and the MPU 20, respectively. In addition, the connection unit 50 is not limited to a unit that physically connects the MPU 20 and the RAM unit 40, but the connection unit 50 includes a unit that communicably connects the MPU 20 and the RAM unit 40 in a wireless manner (for example, TCI).

The spacer 60 is placed on the upper surface of the RAM unit 40. The spacer 60 is configured to have, for example, a rectangular shape in a plan view. The spacer 60 is made of, for example, silicon. The thickness of the spacer 60 is configured to be substantially equal to the thickness of the MPU 20 or larger than the thickness of the MPU 20. More preferably, the height from the upper surface of the interposer 10 to the upper surface of the spacer 60 is substantially equal to or is equal to the height from the upper surface of the interposer 10 to the upper surface of the MPU 20 connected to the interposer 10 by the pillars 30. The spacer 60 is disposed to be adjacent to the MPU 20 in a direction intersecting the lamination direction C of the RAM unit 40. In the present embodiment, the spacer 60 is disposed to be adjacent to the MPU 20 so as to interpose the side surface of the MPU 20. Among the ends of the spacer 60, the end opposite to the side facing the MPU 20 is disposed to protrude from the RAM unit 40 in the direction intersecting the lamination direction C of the RAM unit 40. Specifically, among the ends of the spacer 60, the end opposite to the side facing the MPU 20 is disposed to protrude from the RAM unit 40 in the direction opposite to the side facing the MPU 20.

In addition, in a case where there is no need for a gap between the MPU 20 and the RAM unit 40, the thickness of the spacer 60 is substantially equal to the thickness of the MPU 20. In this case, the connection unit 50 is mounted on the RAM unit 40 and the MPU 20. For example, in a case where the MPU 20 and the RAM unit 40 are connected by TCI or Cu hybrid bonding technique, the connection unit 50 is mounted on the RAM unit 40 and the MPU 20 as a coil (not illustrated) disposed inside the RAM unit 40 and the MPU 20 or a Cu pad (not illustrated) exposed on the upper surface of the RAM unit 40 and the lower surface of the MPU 20.

The support 70 is made of, for example, silicon. The support 70 is formed to have, for example, a substantially rectangular shape in a plan view. The support 70 is placed on the upper surface of the spacer 60 and the upper surface of the MPU 20. The support 70 is formed with such a size that can cover the spacer 60 and the MPU 20 in a plan view.

Next, operations of the semiconductor module 1 will be described. First, a power is supplied from the interposer 10 to the MPU 20. In addition, a power is supplied from the interposer 10 to the RAM unit 40. In addition, the MPU 20 is ground-connected to the interposer 10. The RAM unit 40 is ground-connected to the interposer 10. In addition, a power and a ground may be supplied from the MPU 20 to the RAM unit 40 via the connection unit 50 therebetween.

In a case where a data is stored in the RAM unit 40, first, the data is transmitted from the interposer 10 to the MPU 20 via the pillar 30. The MPU 20 transmits a calculation result calculated on the basis of the transmitted data to the RAM unit as a store signal. That is, the store signal transmitted from the MPU 20 is transmitted to the RAM unit 40 through the circuit surface of the MPU 20 and the connection unit 50. The RAM unit 40 stores the data included in the store signal on the basis of the address included in the store signal.

On the other hand, in a case where a data is loaded from the RAM unit 40, first, a load signal is transmitted from the interposer 10 to the MPU 20 via the pillar 30. That is, the load signal transmitted from the MPU 20 is transmitted to the RAM unit 40 through the circuit surface of the MPU 20 and the connection unit 50.

The RAM unit 40 loads a data from a corresponding address on the basis of the address included in the load signal. The RAM unit 40 transmits the loaded data to the MPU 20 via the connection unit 50.

Next, the structure of the semiconductor module 1 will be described. First, as illustrated in FIG. 3, the MPU 20 having a circuit surface is prepared. Next, as illustrated in FIG. 4, a portion of the connection unit 50 is formed at both ends of the circuit surface of the MPU 20. Next, as illustrated in FIG. 5, a plurality of the pillars 30 are formed at the center of the circuit surface of the MPU 20.

In addition, as illustrated in FIG. 6, the RAM unit 40 in which a plurality of dies are laminated is prepared. Next, as illustrated in FIG. 7, a portion of the connection unit 50 is formed at one end of the upper surface (upper side in FIG. 7) of the RAM unit 40. Next, as illustrated in FIG. 8, a plurality of micro bumps M are formed on the lower surface of the RAM unit 40.

Next, the support 70 is prepared as illustrated in FIG. 9. The support 70 is disposed upside down in the lamination direction C (the upward and downward directions are illustrated upside down in FIGS. 9 to 12 below). Next, as illustrated in FIG. 10, the MPU 20 is placed on one surface (lower surface) of the support 70. Specifically, the MPU 20 is placed on the support 70 in a state where the upper surface faces one surface (lower surface) of the support 70. Next, as illustrated in FIG. 11, the spacer 60 is placed on one surface (lower surface) of the support 70 in a state where the spacer 60 is adjacent to the MPU 20. Next, as illustrated in FIG. 12, the RAM unit 40 is placed on the spacer 60. Accordingly, the upper surface of the RAM unit 40 faces the lower surface of the spacer 60. At this time, a portion of the connection unit 50 configured in the RAM unit 40 and a portion of the connection unit 50 configured in the MPU 20 are disposed so as to overlap. Then, by allowing the upper surface of the interposer 10 to be connected to the pillars 30 connected to the MPU 20 and the bumps M formed in the RAM unit 40, the structure of the semiconductor module 1 as illustrated in FIG. 2 is realized.

According to the semiconductor module 1 according to the embodiment as described above, the following effects can be obtained.

(1) A semiconductor module includes a logic chip, a RAM unit 40 which is a lamination-type RAM module, a spacer 60 which is disposed to be laminated along a lamination direction of the RAM unit 40, an interposer 10 which is electrically connected to each of the logic chip and the RAM unit 40, and a connection unit 50 which communicably connects the logic chip and the RAM unit 40. The logic chip and the spacer 60 are disposed to be adjacent in a direction intersecting the lamination direction of the RAM unit 40, the RAM unit 40 is placed on the interposer 10, one end of is disposed so as to overlap with one end of the logic chip in the lamination direction, and the connection unit 50 connects one end of the RAM unit 40 and one end of the logic chip. Accordingly, since the MPU 20 and each of the pair of RAM units 40 can be directly connected by the connection unit 50, it is possible to shorten the signal line (the length of the connection unit 50) between the MPU 20 and each of the pair of RAM units 40. Therefore, the bandwidth between the MPU 20 and the pair of RAM units 40 can be increased.

(2) In the semiconductor module, a pair of the RAM unit 40 and the spacer 60 are provided with the logic chip interposed therebetween, and the connection unit 50 is provided for each RAM unit 40. Accordingly, since each RAM unit 40 is individually connected to the MPU 20 by the connection unit 50, a plurality of RAM units 40 can be easily connected to the MPU 20, and the capacity of the RAM unit 40 can be easily increased.

(3) The thickness of the spacer 60 is substantially equal to or larger than the thickness of the logic chip. Accordingly, it is possible to stably dispose the support 70 while connecting the lower surface of the MPU 20 to the upper surface of the RAM unit 40.

(4) Among the ends of the spacer 60, the end opposite to the side facing the logic chip is disposed to protrude from the RAM unit 40 in a direction intersecting the lamination direction of the RAM unit 40. Accordingly, since the exposed area of the spacer 60 is increased in comparison with the case where the side surface of the spacer 60 is flush with the side surface of the RAM unit 40, it is possible to improve the heat dissipation of the heat generated in the RAM unit 40. In addition, since a paste or the like for lamination can be applied to the entire surface of the RAM unit 40, the structure is stabilized, so that the inclination of the RAM unit 40 can be prevented.

(5) The semiconductor module further includes a plurality of pillars 30 which communicably connect the interposer 10 and the logic chip, each of the plurality of pillars 30 being longer than the thickness of the RAM unit 40 in the lamination direction. Accordingly, it is possible to dispose the position of the MPU 20 at a distance from the upper surface of the interposer 10 by the length of the pillar 30. Therefore, it is possible to allow a portion of the upper surface of the RAM unit to face a portion of the lower surface of the MPU 20, and thus, it is possible to shorten the signal line (the length of the connection unit 50).

Although the preferred embodiment of the semiconductor module according to the present invention has been described above, the present invention is not limited to the above-described embodiment, and the present invention can be appropriately modified.

For example, as illustrated in FIG. 13, a plurality of MPUs 20 may be provided for one interposer 10, and a pair of the RAM units 40 and a pair of the spacers 60 may be provided for each MPU 20. Accordingly, since the RAM unit 40 can be connected to each of the plurality of MPUs 20, the signal line (the length of the connection unit 50) between the MPU 20 and the RAM unit 40 can be shortened, and even in a case where the plurality of MPUs 20 exist, it is possible to widen the bandwidth.

In addition, in the above-described embodiment, a pair of the RAM unit 40 and the spacer 60 are described to be provided so as to interpose the MPU 20, but the present invention is not limited thereto. For example, the RAM unit 40 and the spacer 60 may be disposed on only one side of the MPU 20. In addition, the RAM unit 40 and the spacer 60 may be disposed on three sides of the MPU 20 or may be disposed on four sides so as to surround the MPU 20.

In addition, the arithmetic unit is not limited to the MPU 20 and may be widely applied to all logic chips. The memory is not limited to the DRAM, but the memory may be widely applied to a random access memory (RAM) including a nonvolatile RAM (for example, an MRAM, a ReRAM, an FeRAM, and the like).

### EXPLANATION OF REFERENCE NUMERALS

1 SEMICONDUCTOR MODULE
10 INTERPOSER
20 MPU
30 PILLAR
40 RAM UNIT
50 CONNECTION UNIT
60 SPACER
70 SUPPORT

1. A semiconductor module comprising:
a logic chip;
a RAM unit which is a lamination-type RAM module;
a spacer which is disposed to be laminated over the RAM unit along a lamination direction;
an interposer which is electrically connected to each of the logic chip and the RAM unit; and
a connection unit which communicably connects the logic chip and the RAM unit,
wherein the logic chip and the spacer are disposed to be adjacent to each other in a direction intersecting the lamination direction of the RAM unit,
wherein the RAM unit is placed on the interposer, and one end of the RAM unit is disposed to overlap one end of the logic chip in the lamination direction, and
wherein the connection unit communicably connects the one end of the RAM unit and the one end of the logic chip.

2. The semiconductor module according to claim 1,
wherein a pair of the RAM unit and the spacer are provided with the logic chip interposed therebetween, and
wherein the connection unit is provided for each of the RAM units.

3. The semiconductor module according to claim 1, wherein a thickness of the spacer is substantially equal to a thickness of the logic chip.

4. The semiconductor module according to claim 1, wherein a thickness of the spacer is larger than a thickness of the logic chip.

5. The semiconductor module according to claim 1, wherein among ends of the spacer, an end opposite to a side facing the logic chip is disposed to protrude from the RAM unit in a direction intersecting the lamination direction of the RAM unit.

6. The semiconductor module according to claim 1, further comprising a plurality of pillars which communicably connect the interposer and the logic chip, each pillar being longer than a thickness of the RAM unit in the lamination direction.

7. The semiconductor module according to claim 1,
wherein a plurality of the logic chips are provided for one interposer, and
wherein a pair of the RAM units and a pair of the spacers are provided for each of the logic chips.
